(19) United States
(12) Patent Application Publication
(10) Pub. No.: US 2013/0176518 A1
(43) Pub. Date: Jul. 11, 2013

(54) BACK-TO-BACK DISPLAYS

(71) Applicant: QUALCOMM MEMS TECHNOLOGIES, INC., San Diego, CA (US)

(72) Inventors: Jeffrey B. Sampsell, Pueblo West, CO (US); Clarence Chui, San Jose, CA (US); Brian J. Gally, Los Gatos, CA (US)

(73) Assignee: QUALCOMM MEMS TECHNOLOGIES, INC., San Diego, CA (US)

(21) Appl. No.: 13/782,666

(22) Filed: Mar. 1, 2013

Related U.S. Application Data
(63) Continuation of application No. 11/439,012, filed on May 22, 2006, now abandoned.

(51) Int. Cl. G02B 26/00; H05K 5/00

(52) U.S. Cl. CPC G02B 26/001; H05K 5/0017
USPC 349/58; 359/290; 361/809; 313/498; 313/582; 29/428

(57) ABSTRACT

Two-sided, back-to-back displays are formed by sealing the backplates of two displays against one another. Mechanical parameters of the backplates, e.g., stiffness and strength, do not meet the requirements for standalone one-sided displays which are otherwise similar to the two displays. However, when sealed against one another, the backplates reinforce each other to meet or exceed the requirements for both one-sided and two-sided displays. The presence of backplates on each of the constituent one-sided displays allows one or both of those displays to be individually tested, thereby increasing the production yield of the back-to-back displays. The display elements of the displays can comprise interferometric modulators.

### CROSS-REFERENCE TO RELATED APPLICATIONS

This application is a continuation of U.S. patent application Ser. No. 11/439,012, filed May 22, 2006, entitled “BACK-TO-BACK DISPLAYS,” which is incorporated by reference herein in its entirety and for all purposes.

### FIELD OF THE INVENTION

This invention relates to microelectromechanical systems (MEMS) and, more particularly, to devices using such systems in picture elements in displays and to methods of forming the same.

### DESCRIPTION OF THE RELATED TECHNOLOGY

Microelectromechanical systems (MEMS) include micro mechanical elements, actuators, and electronics. Micromechanical elements may be created using deposition, etching, and or other micromachining processes that etch away parts of substrates and/or deposited material layers or that add layers to form electrical and electromechanical devices. One type of MEMS device is called an interferometric modulator. As used herein, the term interferometric modulator or interferometric light modulator refers to a device that selectively absorbs and/or reflects light using the principles of optical interference. In certain embodiments, an interferometric modulator may comprise a pair of conductive plates, one or both of which may be transparent and/or reflective in whole or part and capable of relative motion upon application of an appropriate electrical signal. In a particular embodiment, one plate may comprise a stationary layer deposited on a substrate and the other plate may comprise a metallic membrane separated from the stationary layer by an air gap. As described herein in more detail, the position of one plate in relation to another can change the optical interference of light incident on the interferometric modulator. Such devices have a wide range of applications, and it would be beneficial in the art to utilize and/or modify the characteristics of these types of devices so that their features can be exploited in improving existing products and creating new products that have not yet been developed.

### SUMMARY OF CERTAIN EMBODIMENTS

In one aspect, a two-sided electronic display device is provided. The display device comprises a first display device comprising a first transparent substrate, a first backplate and a first opaque layer comprising a first set of pixel elements. The first opaque layer is disposed between the first transparent substrate and the first backplate. The first set of pixel elements is configured to transmit light through the first transparent substrate. The display device also comprises a second display device comprising a second transparent substrate, a second backplate and a second opaque layer comprising a second set of pixel elements. The second opaque layer is disposed between the second transparent substrate and the second backplate. The second set of pixel elements is configured to transmit light through the second transparent substrate. The display device further comprises a fastener affixing the first backplate to the second backplate.

In another aspect, a display device is provided. The display device comprises a first light modulating means for selectively directing light towards a viewer and a first support means for supporting the first light modulating means. The display device also comprises a second light modulating means for selectively directing light towards the viewer and a second support means for supporting the second light modulating means. The second support means is attached to the first support means on a side of the first support means opposite the first light modulating means.

In yet another aspect, a two-sided display device is provided. The two-sided display comprises a first display comprising a first transparent substrate, a first thin film and a first set of interferometric modulators disposed between the first transparent substrate and the first thin film. The two-sided display also comprises a second display comprising a second transparent substrate, a second backplate and a second set of interferometric modulators disposed between the second transparent substrate and the second backplate. In addition, the two-sided display comprises a fastener affixing the first display to the second backplate.

In another aspect, a method for manufacturing a multi-sided display device is provided. The method comprises providing a first display comprising a first transparent substrate, a first backplate and a first opaque layer comprising a first set of pixel elements. The first opaque layer is disposed between the first transparent substrate and the first backplate. The first set of pixel elements is configured to transmit light through the first transparent substrate. The method also comprises providing a second display comprising a second transparent substrate, a second backplate and a second opaque layer comprising a second set of pixel elements. The second opaque layer is disposed between the second transparent substrate and the second backplate. The second set of pixel elements is configured to transmit light through the second transparent substrate. The method further comprises attaching the first backplate to the second backplate.

In yet another aspect, a method for manufacturing a two-sided display device is provided. The method comprises providing a first partially fabricated display comprising a first transparent substrate and a first set of interferometric modulators. The first set of interferometric modulators is sealed from an ambient environment by overlying the interferometric modulators with a thin film. The interferometric modulators are disposed between the first transparent substrate and the thin film. The method also comprises providing a second display comprising a second transparent substrate, a second backplate and a second set of interferometric modulators disposed between the second transparent substrate and the second backplate. The method further comprises attaching the first partially fabricated display to the second backplate.

In another aspect, a two-sided electronic display device is provided. The display device comprises a first display device comprising a first transparent substrate, a first backplate and a first opaque layer comprising a first set of pixel elements. The first opaque layer is disposed between the first transparent substrate and the first backplate. The first set of pixel elements is configured to transmit light through the first transparent substrate. The display device also comprises a second display device comprising a second transparent substrate, a second backplate and a second opaque layer comprising a second set of pixel elements. The second opaque layer is disposed between the second transparent substrate and the second backplate. The second backplate has a hole sized and shaped to accommodate at least part of the first display device. The second set of pixel elements is configured to transmit light through the second transparent substrate. The display device further comprises a fastener affixing the first display to the second backplate.

In yet another aspect, a method for manufacturing a two-sided display device is provided. The method comprises providing a first partially fabricated display comprising a first transparent substrate and a first set of interferometric modulators. The first set of interferometric modulators is sealed from an ambient environment with a first thin film. The first set of interferometric modulators are disposed between the first transparent substrate and the first thin film. A second partially fabricated display comprising a second transparent substrate and a second set of interferometric modulators is provided. The second set of interferometric modulators is sealed from an ambient environment with a second thin film. The second set of interferometric modulators are disposed between the second transparent substrate and the second thin film. The first and the second partially fabricated displays are attached to a backplate.

### BRIEF DESCRIPTION OF THE DRAWINGS

FIG. 1 is an isometric view depicting a portion of one embodiment of an interferometric modulator display in which a movable reflective layer of a first interferometric modulator is in a relaxed position and a movable reflective layer of a second interferometric modulator is in an actuated position.

FIG. 2 is a system block diagram illustrating one embodiment of an electronic device incorporating a 3×3 interferometric modulator display.

FIG. 3 is a diagram of movable mirror position versus applied voltage for one exemplary embodiment of an interferometric modulator of FIG. 1.

FIG. 4 is an illustration of a set of row and column voltages that may be used to drive an interferometric modulator display.

FIG. 5A illustrates one exemplary frame of display data in the 3×3 interferometric modulator display of FIG. 2.

FIG. 5B illustrates one exemplary timing diagram for row and column signals that may be used to write the frame of FIG. 5A.

FIGS. 6A and 6B are system block diagrams illustrating an embodiment of a visual display device comprising a plurality of interferometric modulators.

FIG. 7A is a cross section of the device of FIG. 1.

FIG. 7B is a cross section of an alternative embodiment of an interferometric modulator.

FIG. 7C is a cross section of another alternative embodiment of an interferometric modulator.

FIG. 7D is a cross section of yet another alternative embodiment of an interferometric modulator.

FIG. 7E is a cross section of an additional alternative embodiment of an interferometric modulator.

FIG. 8 is a cross section of an embodiment of a two-sided display device.

FIG. 9 is a cross section of an alternative embodiment of a two-sided display device.

FIG. 10 is a cross section of another alternative embodiment of a two-sided display device.

FIG. 11 is a cross section of yet another alternative embodiment of a two-sided display device.

FIG. 12 is a cross section of an additional alternative embodiment of a two-sided display device.

FIG. 13 is a cross section of a further alternative embodiment of a two-sided display device.

FIG. 14 is a cross section of an embodiment of a partially fabricated display.

FIG. 15 is a cross section of another embodiment of a two-sided display device.

FIG. 16 is a cross section of yet another embodiment of a two-sided display device.

FIG. 17 is a cross section of another embodiment of a two-sided display device.

FIG. 18 is a cross section of yet another embodiment of a two-sided display device.

### DETAILED DESCRIPTION OF THE PREFERRED EMBODIMENTS

The following detailed description is directed to certain specific embodiments of the invention. However, the invention can be embodied in a multitude of different ways. In this description, reference is made to the drawings wherein like parts are designated with like numerals throughout. As will be apparent from the following description, the embodiments may be implemented in any device that is configured to display an image, whether in motion (e.g., video) or stationary (e.g., still image), and whether textual or pictorial. More particularly, it is contemplated that the embodiments may be implemented in or associated with a variety of electronic devices such as, but not limited to, mobile telephones, wireless devices, personal data assistants (PDAs), hand-held or portable computers, GPS receivers/navigators, cameras, MP3 players, camcorders, game consoles, wrist watches, clocks, calculators, television monitors, flat panel displays, computer monitors, auto displays (e.g., odometer display, etc.), cockpit controls and/or displays, display of camera views (e.g., display of a rear view camera in a vehicle), electronic photographs, electronic billboards or signs, projectors, architectural structures, packaging, and aesthetic structures (e.g., display of images on a piece of jewelry). MEMS devices of similar structure to those described herein can also be used in non-display applications such as in electronic switching devices.

In one aspect, the present invention is a two-sided display having a separate viewing surface on each side of the display. The two-sided display is formed by attaching two one-sided displays back-to-back against each other. In one embodiment, each of the two one-sided displays has a transparent substrate, on which interferometric modulators are formed. It will be appreciated that the interferometric modulators are reflective devices which have a layer opaque to light, for example, a reflective mirror. The displays may have a backplate which seals against the transparent substrates and is spaced from the interferometric modulators. The backplate serves various structural functions, including: 1) providing structural stiffness for the display; 2) protecting the interferometric modulators from undesired physical contact; and 3) sealing the interferometric modulators from the ambient environment, e.g., the ambient atmosphere, which can include undesirable contaminants such as moisture. In order to successfully perform these structural functions, the backplates of standalone one-sided displays typically must meet particular parameters, e.g., for minimum stiffness. In one embodiment, the backplate of one or both of the constituent displays of the present invention do not meet the structural parameters, such as stiffness, for a standalone one-sided display because the backplate is too thin and/or because the backplate has a hole. However, by attaching two backplates back-to-back, the backplates can reinforce each other, thereby providing the desired stiffness while allowing for a relatively thin two-sided display.

In some embodiments, one or both of the backplates of the displays forming the two-sided display are relatively thin and do not meet stiffness specifications for a standalone one-sided display which is otherwise similar. Preferably, this thinness is localized in areas where the two displays overlap. For example, if the two displays have backplates that completely overlap, the thinness of the backplate can extend over the entire area of the two backplates. In some embodiments, if one of the one-sided displays is smaller than the other, the backplate of the larger display has a thin portion which substantially overlaps the backplate of the smaller display. This thin area can take the form of a recess into which the smaller display can fit. In other embodiments, the thin area can be a recess which faces the interferometric modulators and can accommodate desiccant, as discussed below. In other embodiments, the backplate of one display is provided with a hole, into which parts of the other display can fit.

Advantageously, as discussed further below, one or both of the constituent displays of the two-sided can be individually tested, thereby improving overall production yields. Thus, by this testing, the functioning of the displays, including the electromechanical functioning of the pixel elements, e.g., interferometric modulators, can be investigated to ensure they meet minimum specifications. In addition, in some embodiments, the constituent displays can be tested before any backplate is attached to the display. For example, a film which forms a sufficiently tight seal can be attached to the transparent substrate to allow the display to be tested before a backplate is attached. Advantageously, this can prevent a backplate from being attached to a defective display, thereby eliminating the expense and time of providing and attaching the backplate. In addition, individual testing of one or both of the constituent displays of the two-sided display can increase overall production yield by preventing the attachment of a defective display with a “good” display that meets specifications. Thus, the good display is not unnecessarily discarded with the defective display.

Reference will now be made to the Figures.

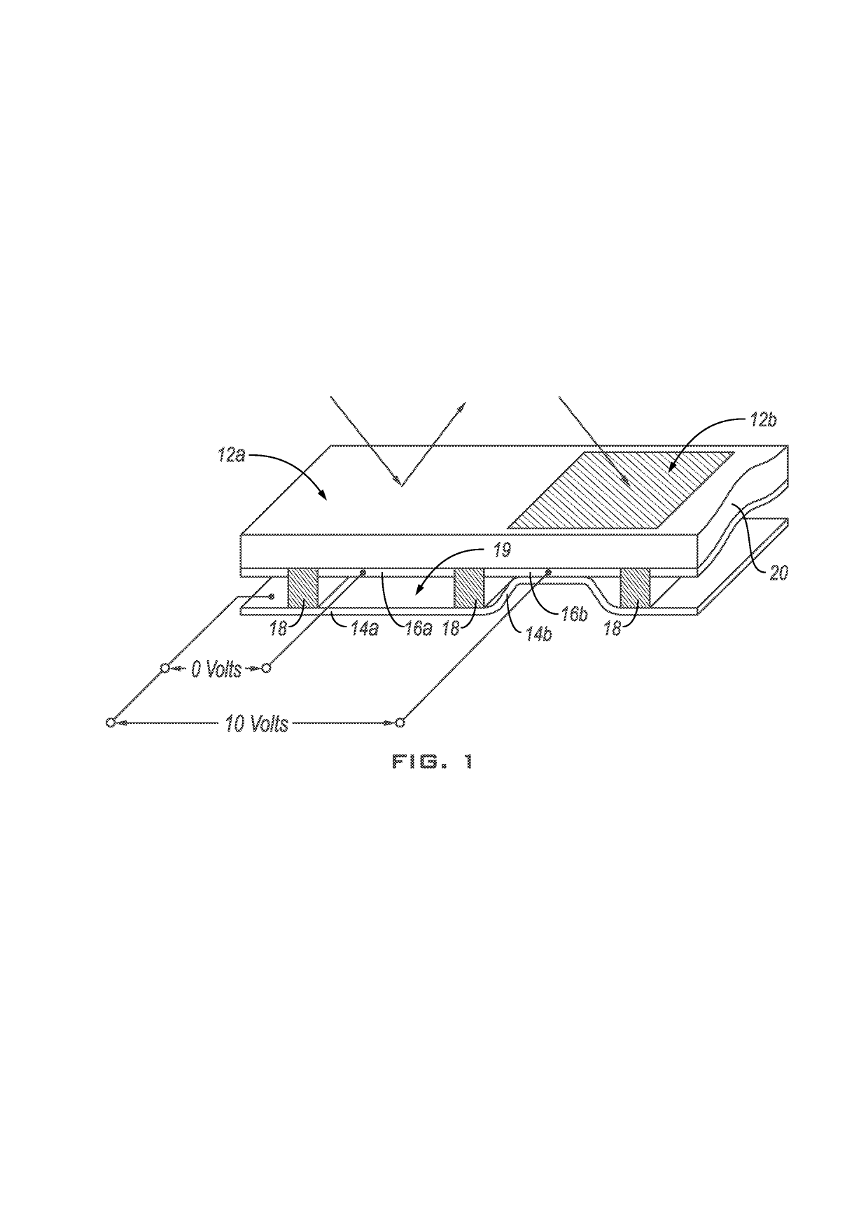

One interferometric modulator display embodiment comprising an interferometric MEMS display element is illustrated in FIG. 1. In these devices, the pixels are in either a bright or dark state. In the bright (“on” or “open”) state, the display element reflects a large portion of incident visible light to a user. When in the dark (“off” or “closed”) state, the display element reflects little incident visible light to the user. Depending on the embodiment, the light reflectance properties of the “on” and “off” states may be reversed. MEMS pixels can be configured to reflect predominantly at selected colors, allowing for a color display in addition to black and white.

FIG. 1 is an isometric view depicting two adjacent pixels in a series of pixels of a visual display, wherein each pixel comprises a MEMS interferometric modulator. In some embodiments, an interferometric modulator display comprises a row/column array of these interferometric modulators. Each interferometric modulator includes a pair of reflective layers positioned at a variable and controllable distance from each other to form a resonant optical cavity with at least one variable dimension. In one embodiment, one of the reflective layers may be moved between two positions. In the first position, referred to herein as the relaxed position, the movable reflective layer is positioned at a relatively large distance from a fixed partially reflective layer. In the second position, referred to herein as the actuated position, the movable reflective layer is positioned more closely adjacent to the partially reflective layer. Incident light that reflects from the two layers interferes constructively or destructively depending on the position of the movable reflective layer, producing either an overall reflective or non-reflective state for each pixel.

The depicted portion of the pixel array in FIG. 1 includes two adjacent interferometric modulators 12a and 12b. In the interferometric modulator 12a on the left, a movable reflective layer 14a is illustrated in a relaxed position at a predetermined distance from an optical stack 16a, which includes a partially reflective layer. In the interferometric modulator 12b on the right, the movable reflective layer 14b is illustrated in an actuated position adjacent to the optical stack 16b.

The optical stacks 16a and 16b (collectively referred to as optical stack 16), as referenced herein, typically comprise of several fused layers, which can include an electrode layer, such as indium tin oxide (ITO), a partially reflective layer, such as chromium, and a transparent dielectric. The optical stack 16 is thus electrically conductive, partially transparent and partially reflective, and may be fabricated, for example, by depositing one or more of the above layers onto a transparent substrate 20. The partially reflective layer can be formed from a variety of materials that are partially reflective such as various metals, semiconductors, and dielectrics. The partially reflective layer can be formed of one or more layers of materials, and each of the layers can be formed of a single material or a combination of materials.

In some embodiments, the layers of the optical stack are patterned into parallel strips, and may form row electrodes in a display device as described further below. The movable reflective layers 14a, 14b may be formed as a series of parallel strips of a deposited metal layer or layers (orthogonal to the row electrodes of 16a, 16b) deposited on top of posts 18 and an intervening sacrificial material deposited between the posts 18. When the sacrificial material is etched away, the movable reflective layers 14a, 14b are separated from the optical stacks 16a, 16b by a defined gap 19. A highly conductive and reflective material such as aluminum may be used for the reflective layers 14, and these strips may form column electrodes in a display device.

With no applied voltage, the cavity 19 remains between the movable reflective layer 14a and optical stack 16a, with the movable reflective layer 14a in a mechanically relaxed state, as illustrated by the pixel 12a in FIG. 1. However, when a potential difference is applied to a selected row and column, the capacitor formed at the intersection of the row and column electrodes at the corresponding pixel becomes charged, and electrostatic forces pull the electrodes together. If the voltage is high enough, the movable reflective layer 14 is deformed and is forced against the optical stack 16. A dielectric layer (not illustrated in this Figure) within the optical stack 16 may prevent shorting and control the separation distance between layers 14 and 16, as illustrated by pixel 12b on the right in FIG. 1. The behavior is the same regardless of the polarity of the applied potential difference. In this way, row/column actuation that can control the reflective vs. non-reflective pixel states is analogous in many ways to that used in conventional LCD and other display technologies.

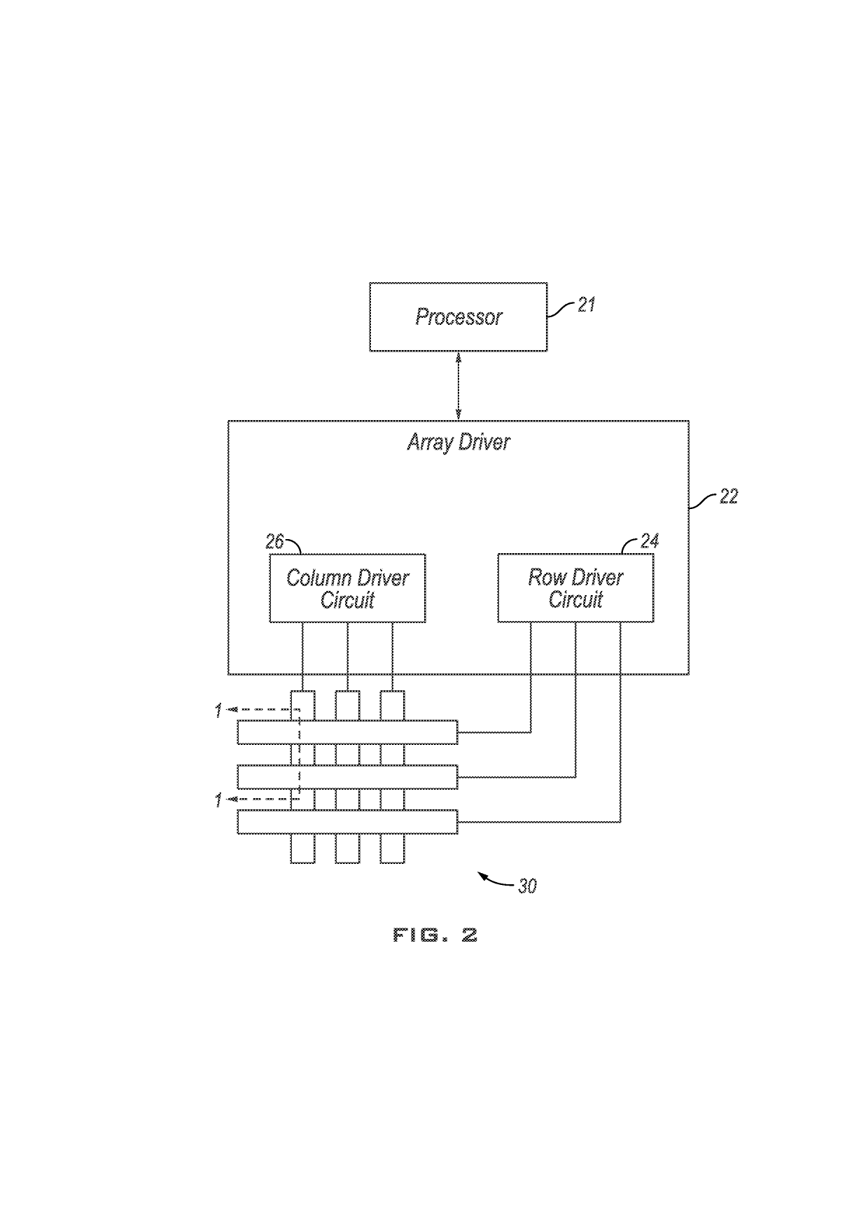

FIGS. 2 through 5B illustrate one exemplary process and system for using an array of interferometric modulators in a display application.

FIG. 2 is a system block diagram illustrating one embodiment of an electronic device that may incorporate aspects of the invention. In the exemplary embodiment, the electronic device includes a processor 21 which may be any general purpose single- or multi-chip microprocessor such as an ARM, Pentium®, Pentium II®, Pentium III®, Pentium IV®, Pentium® Pro, an 8051, a MIPS®, a Power PC®, an ALPHA®, or any special purpose microprocessor such as a digital signal processor, microcontroller, or a programmable gate array. As is conventional in the art, the processor 21 may be configured to execute one or more software modules. In addition to executing an operating system, the processor may be configured to execute one or more software applications, including a web browser, a telephone application, an email program, or any other software application.

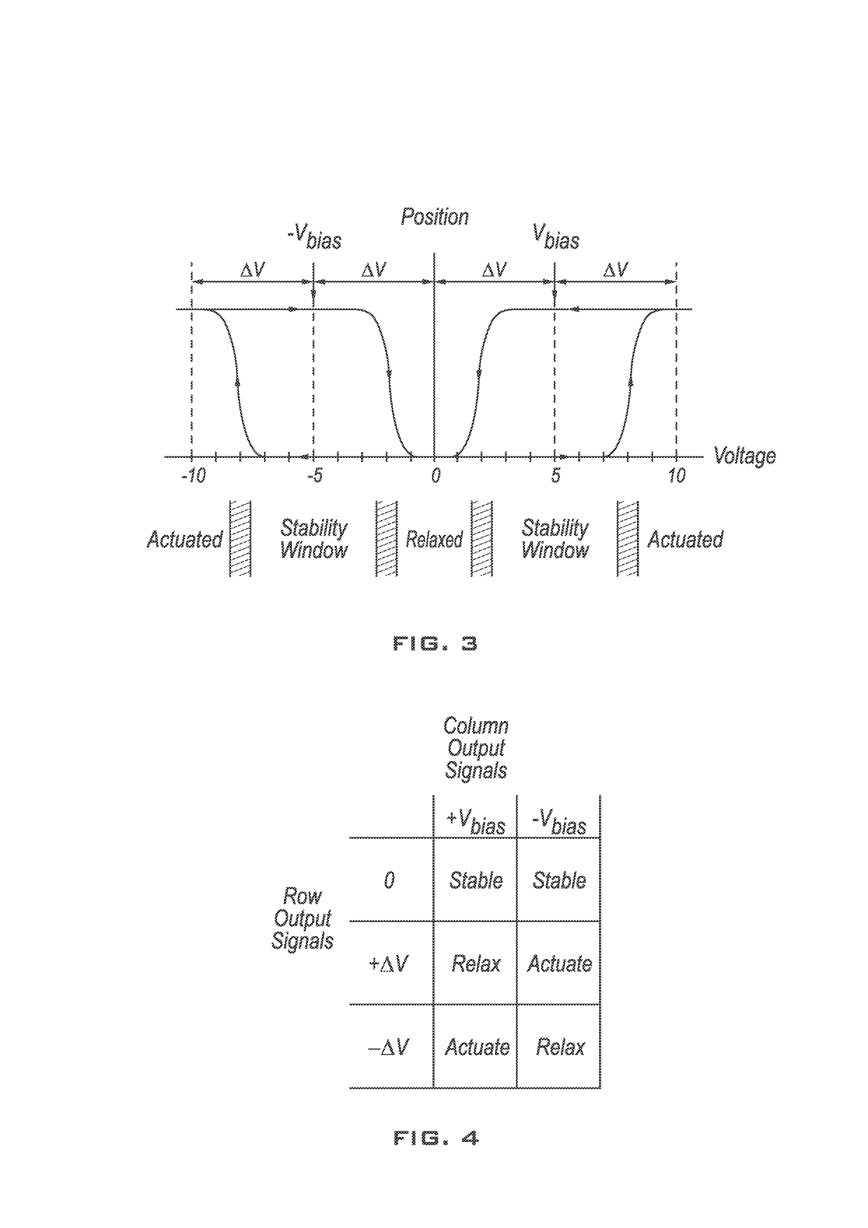

In one embodiment, the processor 21 is also configured to communicate with an array driver 22. In one embodiment, the array driver 22 includes a row driver circuit 24 and a column driver circuit 26 that provide signals to a display array or panel 30. The cross section of the array illustrated in FIG. 1 is shown by the lines 1-1 in FIG. 2. For MEMS interferometric modulators, the row/column actuation protocol may take advantage of a hysteresis property of these devices illustrated in FIG. 3. It may require, for example, a 10 volt potential difference to cause a movable layer to deform from the relaxed state to the actuated state. However, when the voltage is reduced from that value, the movable layer maintains its state as the voltage drops back below 10 volts. In the exemplary embodiment of FIG. 3, the movable layer does not relax completely until the voltage drops below 2 volts. There is thus a range of voltage, about 3 to 7 V in the example illustrated in FIG. 3, where there exists a window of applied voltage within which the device is stable in either the relaxed or actuated state. This is referred to herein as the “hysteresis window” or “stability window.” For a display array having the hysteresis characteristics of FIG. 3, the row/column actuation protocol can be designed such that during row strobing, pixels in the strobed row that are to be actuated are exposed to a voltage difference of about 10 volts, and pixels that are to be relaxed are exposed to a voltage difference of close to zero volts. After the strobe, the pixels are exposed to a steady state voltage difference of about 5 volts such that they remain in whatever state the row strobe put them in. After being written, each pixel sees a potential difference within the “stability window” of 3-7 volts in this example. This feature makes the pixel design illustrated in FIG. 1 stable under the same applied voltage conditions in either an actuated or relaxed pre-existing state. Since each pixel of the interferometric modulator, whether in the actuated or relaxed state, is essentially a capacitor formed by the fixed and moving reflective layers, this stable state can be held at a voltage within the hysteresis window with almost no power dissipation. Essentially no current flows into the pixel if the applied potential is fixed.

In typical applications, a display frame may be created by asserting the set of column electrodes in accordance with the desired set of actuated pixels in the first row. A row pulse is then applied to the row 1 electrode, actuating the pixels corresponding to the asserted column lines. The asserted set of column electrodes is then changed to correspond to the desired set of actuated pixels in the second row. A pulse is then applied to the row 2 electrode, actuating the appropriate pixels in row 2 in accordance with the asserted column electrodes. The row 1 pixels are unaffected by the row 2 pulse, and remain in the state they were set to during the row 1 pulse. This may be repeated for the entire series of rows in a sequential fashion to produce the frame. Generally, the frames are refreshed and/or updated with new display data by continually repeating this process at some desired number of frames per second. A wide variety of protocols for driving row and column electrodes of pixel arrays to produce display frames are also well known and may be used in conjunction with the present invention.

FIGS. 4, 5A, and 5B illustrate one possible actuation protocol for creating a display frame on the 3×3 array of FIG. 2. FIG. 4 illustrates a possible set of column and row voltage levels that may be used for pixels exhibiting the hysteresis curves of FIG. 3. In the FIG. 4 embodiment, actuating a pixel involves setting the appropriate column to −V_{bias}, and the appropriate row to +ΔV, which may correspond to −5 volts and +5 volts respectively Relaxing the pixel is accomplished by setting the appropriate column to +V_{bias}, and the appropriate row to the same +ΔV, producing a zero volt potential difference across the pixel. In those rows where the row voltage is held at zero volts, the pixels are stable in whatever state they were originally in, regardless of whether the column is at +V_{bias}, or −V_{bias}. As is also illustrated in FIG. 4, it will be appreciated that voltages of opposite polarity than those described above can be used, e.g., actuating a pixel can involve setting the appropriate column to +V_{bias}, and the appropriate row to −ΔV. In this embodiment, releasing the pixel is accomplished by setting the appropriate column to −V_{bias}, and the appropriate row to the same −ΔV, producing a zero volt potential difference across the pixel.

FIG. 5B is a timing diagram showing a series of row and column signals applied to the 3×3 array of FIG. 2 which will result in the display arrangement illustrated in FIG. 5A, where actuated pixels are non-reflective. Prior to writing the frame illustrated in FIG. 5A, the pixels can be in any state, and in this example, all the rows are at 0 volts, and all the columns are at +5 volts. With these applied voltages, all pixels are stable in their existing actuated or relaxed states.

In the FIG. 5A frame, pixels (1,1), (1,2), (2,2), (3,2) and (3,3) are actuated. To accomplish this, during a “line time” for row 1, columns 1 and 2 are set to −5 volts, and column 3 is set to +5 volts. This does not change the state of any pixels, because all the pixels remain in the 3-7 volt stability window. Row 1 is then strobed with a pulse that goes from 0, up to 5 volts, and back to zero. This actuates the (1,1) and (1,2) pixels and relaxes the (1,3) pixel. No other pixels in the array are affected. To set row 2 as desired, column 2 is set to −5 volts, and columns 1 and 3 are set to +5 volts. The same strobe applied to row 2 will then actuate pixel (2,2) and relax pixels (2,1) and (2,3). Again, no other pixels of the array are affected. Row 3 is similarly set by setting columns 2 and 3 to −5 volts, and column 1 to +5 volts. The row 3 strobe sets the row 3 pixels as shown in FIG. 5A. After writing the frame, the row potentials are zero, and the column potentials can remain at either +5 or −5 volts, and the display is then stable in the arrangement of FIG. 5A. It will be appreciated that the same procedure can be employed for arrays of dozens or hundreds of rows and columns. It will also be appreciated that the timing, sequence, and levels of voltages used to perform row and column actuation can be varied widely within the general principles outlined above, and the above example is exemplary only, and any actuation voltage method can be used with the systems and methods described herein.

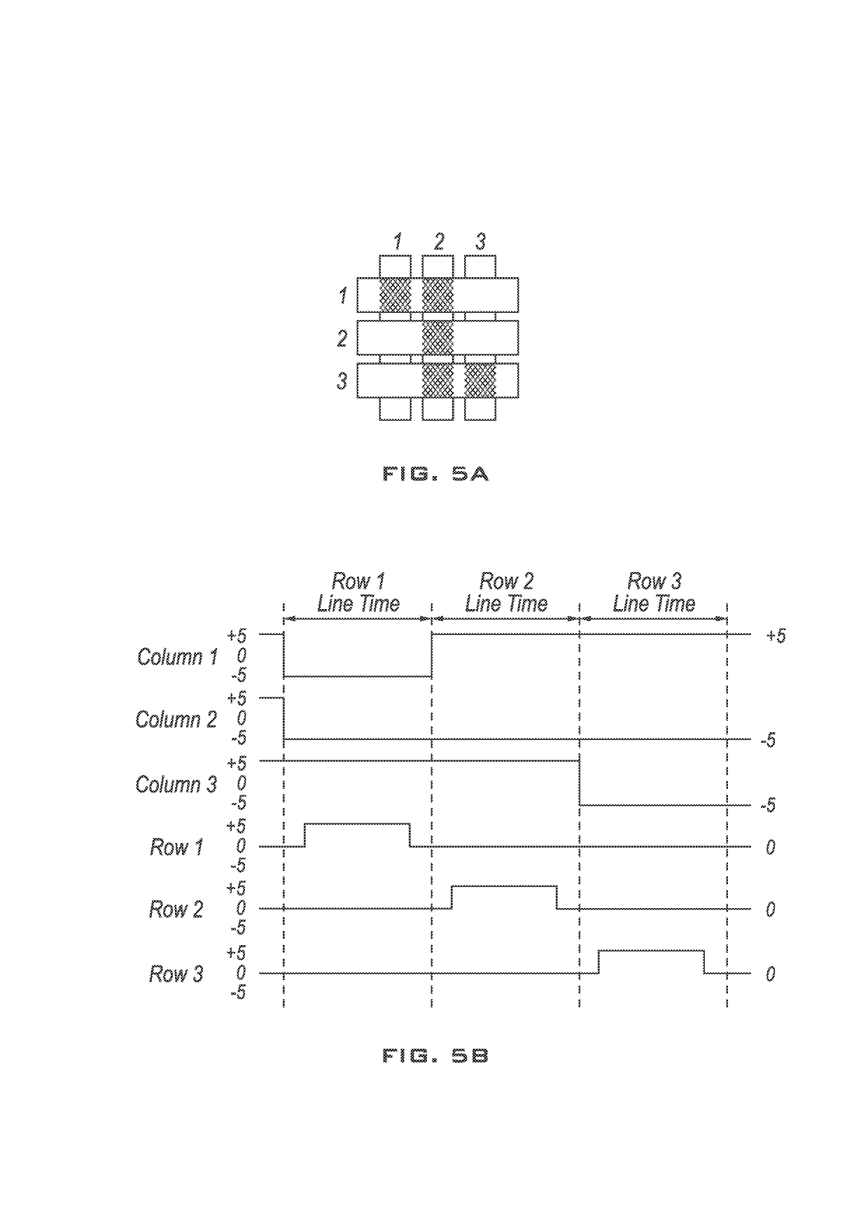

FIGS. 6A and 6B are system block diagrams illustrating an embodiment of a display device 40. The display device 40 can be, for example, a cellular or mobile telephone. However, the same components of display device 40 or slight variations thereof are also illustrative of various types of display devices such as televisions and portable media players.

The display device 40 includes a housing 41, a display 30, an antenna 43, a speaker 44, an input device 48, and a microphone 46. The housing 41 is generally formed from any of a variety of manufacturing processes as are well known to those of skill in the art, including injection molding, and vacuum forming. In addition, the housing 41 may be made from any of a variety of materials, including but not limited to plastic, metal, glass, rubber, and ceramic, or a combination thereof. In one embodiment the housing 41 includes removable portions (not shown) that may be interchanged with other removable portions of different color, or containing different logos, pictures, or symbols.

The display 30 of exemplary display device 40 may be any of a variety of displays, including a bi-stable display, as described herein. In other embodiments, the display 30 includes a flat-panel display, such as plasma, EL, OLED, STN LCD, or TFT LCD as described above, or a non-flat-panel display, such as a CRT or other tube device, as is well known to those of skill in the art. However, for purposes of describing the present embodiment, the display 30 includes an interferometric modulator display, as described herein.

The components of one embodiment of exemplary display device 40 are schematically illustrated in FIG. 6B. The illustrated exemplary display device 40 includes a housing 41 and can include additional components at least partially enclosed therein. For example, in one embodiment, the exemplary display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g. filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 provides power to all components as required by the particular exemplary display device 40 design.

The network interface 27 includes the antenna 43 and the transceiver 47 so that the exemplary display device 40 can communicate with one ore more devices over a network. In one embodiment the network interface 27 may also have some processing capabilities to relieve requirements of the processor 21. The antenna 43 is any antenna known to those of skill in the art for transmitting and receiving signals. In one embodiment, the antenna transmits and receives RF signals according to the IEEE 802.11 standard, including IEEE 802.11(a), (b), or (g). In another embodiment, the antenna transmits and receives RF signals according to the BLUETOOTH standard. In the case of a cellular telephone, the antenna is designed to receive CDMA, GSM, AMPS or other known signals that are used to communicate within a wireless cell phone network. The transceiver 47 pre-processes the signals received from the antenna 43 so that they may be received by and further manipulated by the processor 21. The transceiver 47 also processes signals received from the processor 21 so that they may be transmitted from the exemplary display device 40 via the antenna 43.

In an alternative embodiment, the transceiver 47 can be replaced by a receiver. In yet another alternative embodiment, network interface 27 can be replaced by an image source, which can store or generate image data to be sent to the processor 21. For example, the image source can be a digital video disc (DVD) or a hard-disc drive that contains image data, or a software module that generates image data.

Processor 21 generally controls the overall operation of the exemplary display device 40. The processor 21 receives data, such as compressed image data from the network interface 27 or an image source, and processes the data into raw image data or into a format that is readily processed into raw image data. The processor 21 then sends the processed data to the driver controller 29 or to frame buffer 28 for storage. Raw data typically refers to the information that identifies the image characteristics at each location within an image. For example, such image characteristics can include color, saturation, and gray-scale level.

In one embodiment, the processor 21 includes a microcontroller, CPU, or logic unit to control operation of the exemplary display device 40. Conditioning hardware 52 generally includes amplifiers and filters for transmitting signals to the speaker 45, and for receiving signals from the microphone 46. Conditioning hardware 52 may be discrete components within the exemplary display device 40, or may be incorporated within the processor 21 or other components.

The driver controller 29 takes the raw image data generated by the processor 21 either directly from the processor 21 or from the frame buffer 28 and reformats the raw image data appropriately for high speed transmission to the array driver 22. Specifically, the driver controller 29 reformats the raw image data into a data flow having a raster-like format, such that it has a time order suitable for scanning across the display array 30. Then the driver controller 29 sends the formatted information to the array driver 22. Although a driver controller 29, such as a LCD controller, is often associated with the system processor 21 as a stand-alone Integrated Circuit (IC), such controllers may be implemented in many ways. They may be embedded in the processor 21 as hardware, embedded in the processor 21 as software, or fully integrated in hardware with the array driver 22.

Typically, the array driver 22 receives the formatted information from the driver controller 29 and reformats the video data into a parallel set of waveforms that are applied many times per second to the hundreds and sometimes thousands of leads coming from the display's x-y matrix of pixels.

In one embodiment, the driver controller 29, array driver 22, and display array 30 are appropriate for any of the types of displays described herein. For example, in one embodiment, driver controller 29 is a conventional display controller or a bi-stable display controller (e.g., an interferometric modulator controller). In another embodiment, array driver 22 is a conventional driver or a bi-stable display driver (e.g., an interferometric modulator display). In one embodiment, a driver controller 29 is integrated with the array driver 22. Such an embodiment is common in highly integrated systems such as cellular phones, watches, and other small area displays. In yet another embodiment, display array 30 is a typical display array or a bi-stable display array (e.g., a display including an array of interferometric modulators).

The input device 48 allows a user to control the operation of the exemplary display device 40. In one embodiment, input device 48 includes a keypad, such as a QWERTY keyboard or a telephone keypad, a button, a switch, a touch-sensitive screen, a pressure- or heat-sensitive membrane. In one embodiment, the microphone 46 is an input device for the exemplary display device 40. When the microphone 46 is used to input data to the device, voice commands may be provided by a user for controlling operations of the exemplary display device 40.

Power supply 50 can include a variety of energy storage devices as are well known in the art. For example, in one embodiment, power supply 50 is a rechargeable battery, such as a nickel-cadmium battery or a lithium ion battery. In another embodiment, power supply 50 is a renewable energy source, a capacitor, or a solar cell, including a plastic solar cell, and solar-cell paint. In another embodiment, power supply 50 is configured to receive power from a wall outlet.

In some implementations control programmability resides, as described above, in a driver controller which can be located in several places in the electronic display system. In some cases control programmability resides in the array driver 22. Those of skill in the art will recognize that the above-described optimization may be implemented in any number of hardware and/or software components and in various configurations.

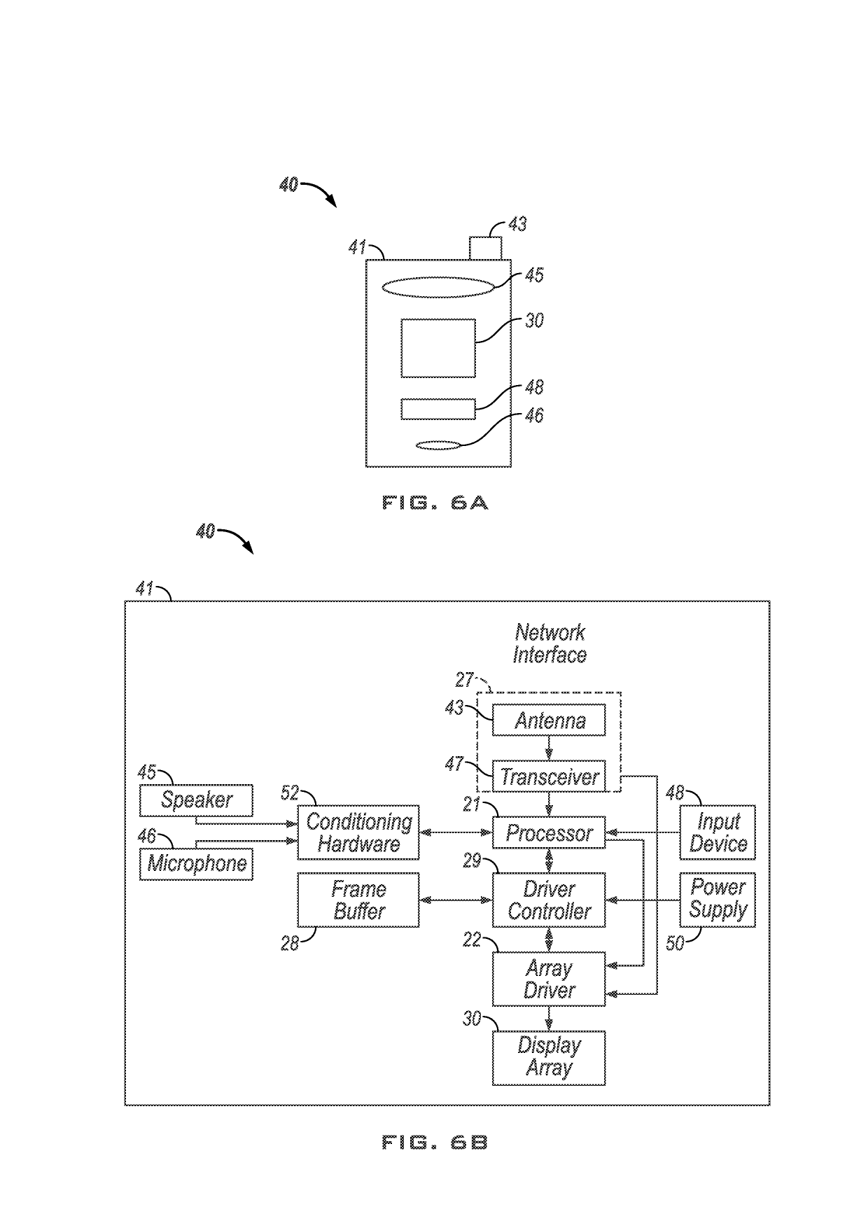

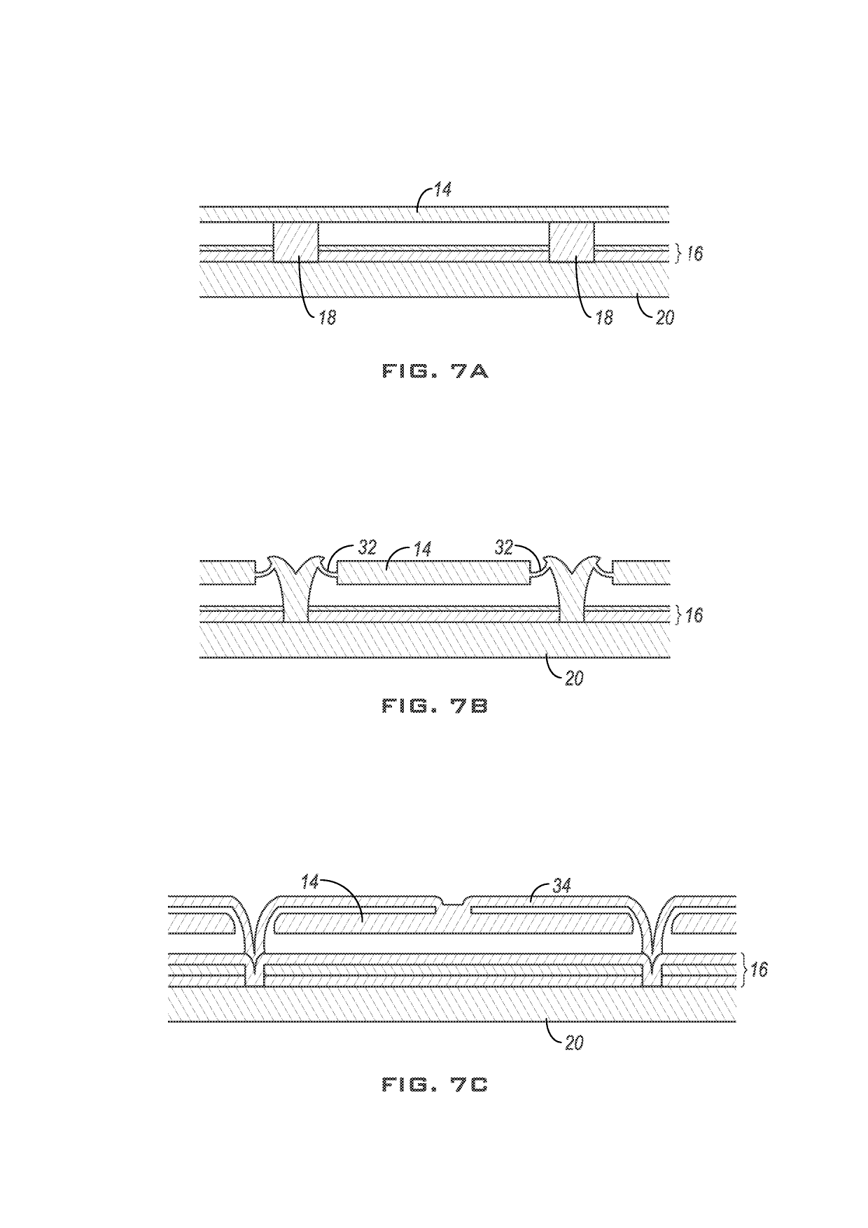

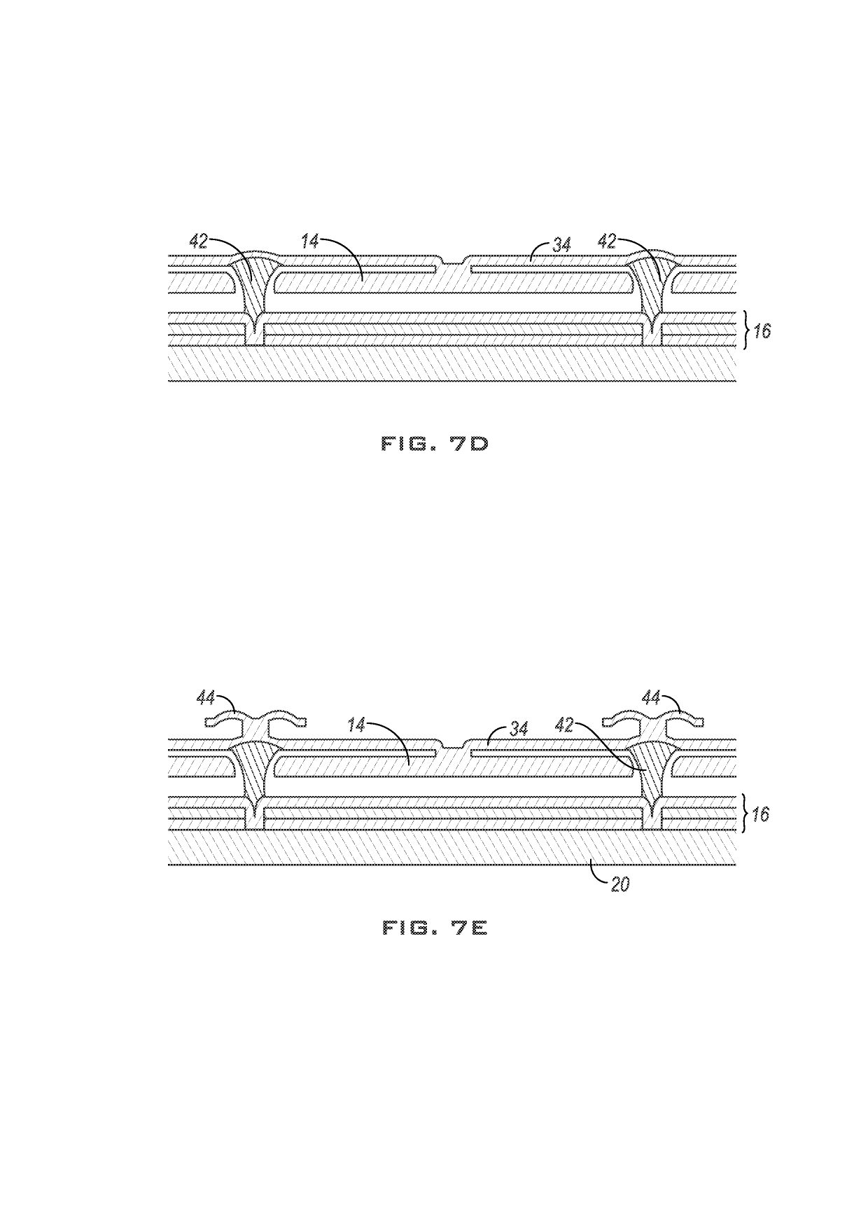

The details of the structure of interferometric modulators that operate in accordance with the principles set forth above may vary widely. For example, FIGS. 7A-7E illustrate five different embodiments of the movable reflective layer 14 and its supporting structures. FIG. 7A is a cross section of the embodiment of FIG. 1, where a strip of metal material 14 is deposited on orthogonally extending supports 18. In FIG. 7B, the moveable reflective layer 14 is attached to supports at the corners only, on tethers 32. In FIG. 7C, the moveable reflective layer 14 is suspended from a deformable layer 34, which may comprise a flexible metal. The deformable layer 34 connects, directly or indirectly, to the substrate 20 around the perimeter of the deformable layer 34. These connections are herein referred to as support posts. The embodiment illustrated in FIG. 7D has support post plugs 42 upon which the deformable layer 34 rests. The movable reflective layer 14 remains suspended over the cavity, as in FIGS. 7A-7C, but the deformable layer 34 does not form the support posts by filling holes between the deformable layer 34 and the optical stack 16. Rather, the support posts are formed of a planarization material, which is used to form support post plugs 42. The embodiment illustrated in FIG. 7E is based on the embodiment shown in FIG. 7D, but may also be adapted to work with any of the embodiments illustrated in FIGS. 7A-7C as well as additional embodiments not shown. In the embodiment shown in FIG. 7E, an extra layer of metal or other conductive material has been used to form a bus structure 44. This allows signal routing along the back of the interferometric modulators, eliminating a number of electrodes that may otherwise have had to be formed on the substrate 20.

In embodiments such as those shown in FIG. 7, the interferometric modulators function as direct-view devices, in which images are viewed from the front side of the transparent substrate 20, the side opposite to that upon which the modulator is arranged. In these embodiments, the reflective layer 14 optically shields the portions of the interferometric modulator on the side of the reflective layer opposite the substrate 20, including the deformable layer 34. This allows the shielded areas to be configured and operated upon without negatively affecting the image quality. Such shielding allows the bus structure 44 in FIG. 7E, which provides the ability to separate the optical properties of the modulator from the electromechanical properties of the modulator, such as addressing and the movements that result from that addressing. This separable modulator architecture allows the structural design and materials used for the electromechanical aspects and the optical aspects of the modulator to be selected and to function independently of each other. Moreover, the embodiments shown in FIGS. 7C-7E have additional benefits deriving from the decoupling of the optical properties of the reflective layer 14 from its mechanical properties, which are carried out by the deformable layer 34. This allows the structural design and materials used for the reflective layer 14 to be optimized with respect to the optical properties, and the structural design and materials used for the deformable layer 34 to be optimized with respect to desired mechanical properties.

### Dual Sided Displays

For many electronic devices, such as those discussed above, there exits a large perceived market pressure to make the devices thin. This is especially true of hand-held devices, such as mobile telephones. To accomplish this goal, there is a large engineering pressure to make every component, including the display, of the products thin.

For example, the pressure for thinness is especially high for clam-shell phones, which are relatively thick when closed because two distinct parts of the phone are stacked one on the other. Much of the pressure falls on the “half shell” that holds a back-to-back display, which comprises two displays oriented back-to-back. The “half shell” typically includes a main display, which is hidden when the phone is closed, and a sub-display, which is visible on the outside of the shell. This nomenclature is derived from the fact that the main display typically has a larger viewing area than the sub-display. As used herein, the main display can, but does not always, have a larger viewing area than the sub-display. Rather, these terms are not limited to a particular display size or display application, but are used simply for ease of reference and for differentiating the constituent displays of a back-to-back display.

Liquid crystal displays (LCD) are a common type of display used in hand-held electronic devices. These displays have pixel elements which transmit light from a backlight to display an image. Because reflective displays, such those using interferometric modulators, have pixel elements which reflect light, rather than transmit it, these displays do not require a backlight. Rather, as noted above, interferometric modulators can comprise a highly reflective layer which is opaque to light. Advantageously, reflective displays offer the potential for very thin displays, since the thickness taken up by the backlight is eliminated.

Various methods have been proposed to make thinner reflective displays, such as those comprising interferometric modulators. For reflective displays, thinner glass layers are an option, especially for the front side of the display, which faces the viewer. For the other side of the display, the backside, removing backplate structures has been viewed as an option. For example, proposals have been made to share a backplate between the two displays (thus eliminating one piece of glass) or to completely remove the backplate structures and use each front glass as a backplate for the other front glass (thus eliminating two pieces of glass). These approaches along with other approaches are discussed in U.S. patent application Ser. Nos. 11/045,800 and 11/187,129, the entire disclosures of which are incorporated by reference herein. Note that when identifying the surfaces of components or layers within a main display and/or a sub-display, the terms of “front side” and “backside” are used with reference to each one of the displays. In other words, a back-to-back display has a front side and a backside for a main display and another front side and a backside for a sub-display.

While typical back-to-back displays have been considered undesirably thick for many applications, removing one or both backplates can present production difficulties. The constituent displays of a back-to-back display which has a shared backplate or which has no backplates typically have exposed pixel elements which cannot be tested until they are attached to one another to form the back-to-back display. Thus, even if only one side of the display is defective and the other side passes inspection, the entire two-sided display must be rejected. This can lower the overall production yield, since both the defective constituent display and a potentially acceptable constituent display are discarded.

Advantageously, preferred embodiments of the invention provide thinner multi-sided, preferably two-sided displays, while allowing one or both displays to be individually tested.

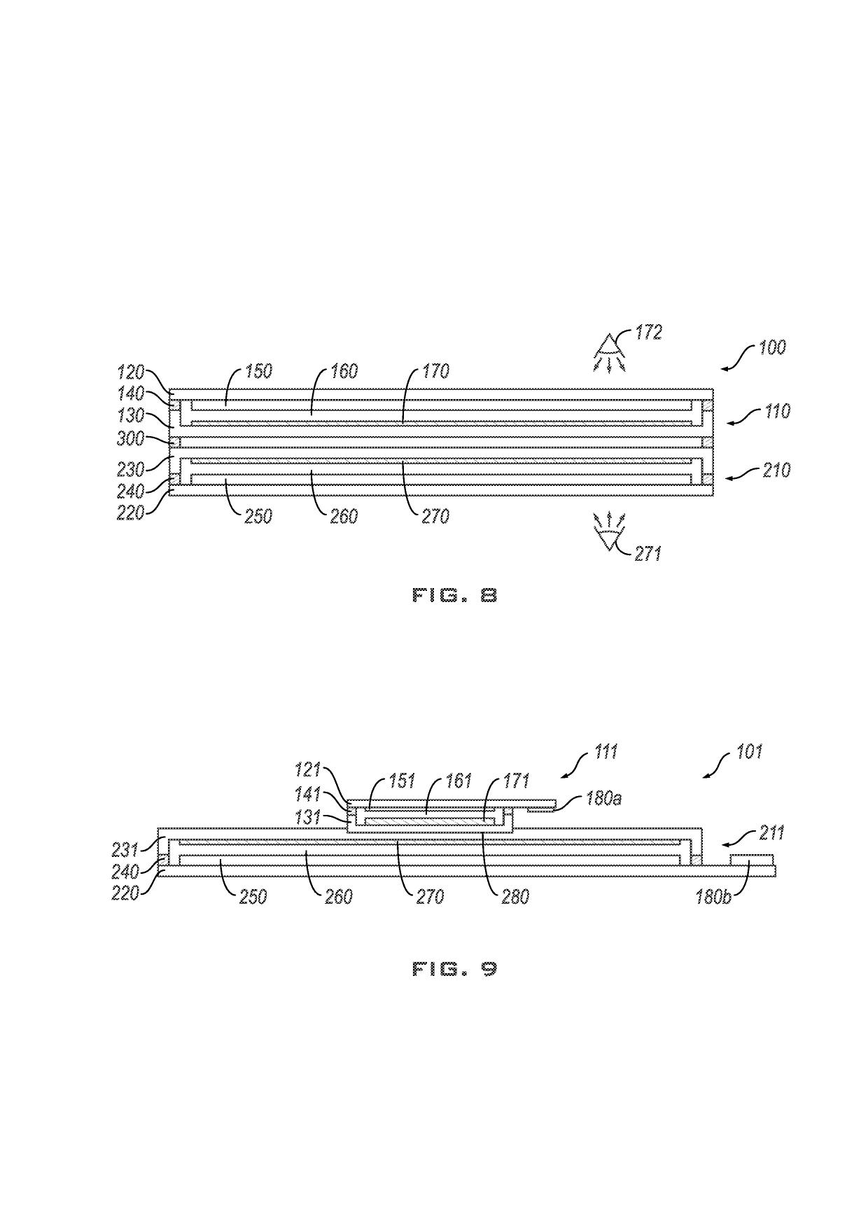

With reference to FIG. 8, a two-sided display 100 is shown. The two-sided display 100 comprises a first, or sub, display 110 and a second, or main, display 210. The sub-display 110 comprises a sub-display transparent substrate 120 which is sealed to a sub-display backplate 130 by a sub-display seal 140. An array of sub-display pixel elements 150, preferably comprising interferometric modulators, is disposed on the transparent substrate 120 in a cavity 160, which can be formed by using, e.g., a backplate which has a large recess that can accommodate the pixel elements 150. The area covered by the pixel elements 150 can be set as desired. For example, the pixel elements 150 can extend across substantially the entire area of the transparent substrate 120, or can extend over only one region of the transparent substrate 120. Because the functioning of the interferometric modulators 150 is sensitive to moisture, the cavity between the transparent substrate 120 and the backplate 130 is preferably provided with desiccant 170 to absorb moisture which may have entered the cavity. A viewer 171, on the front side of the sub-display 110, i.e., the side of the transparent substrate 120 opposite the interferometric modulators 150, views an image formed by the interferometric modulators 150 through the transparent substrate 120.

The main display 210 can be similar in general features to the sub-display 110. As illustrated, the main display 210 comprises a main display transparent substrate 220 sealed to a main display backplate 230 by a main display seal 240. An array of main display pixel elements 250, preferably comprising interferometric modulators, and desiccant 270 is disposed in a cavity 260. A viewer 271 will view an image formed on the pixel elements 250, through the transparent substrate 220.

It will be appreciated that the pixel elements 150 and 250 can be connected to driver display circuits and other electrical systems by various methods known in the art, including but not limited to flex cables, electrical feedthroughs, trace leads, conductive support posts, or micromechanical pressure connectors. Moreover, the pixel elements 150, 250 can share electronics or have independent electronics, such as driver circuits.

With continued reference to FIG. 8, the main display 210 is attached to the sub-display 110 by one or more fasteners 300. It will be appreciated that the fasteners 300 can be any means suitable for rigidly or flexibly attaching the main display 210 to the sub-display 110, preferably such that the backplates 130, 230 can reinforce one another. The fastener can include, without limitation, a glue (e.g., epoxy), an adhesive tape and/or a mechanical fastener, such as a screw or clip. Depending on the type of fastener utilized, the sub-display 110 can be reversibly or irreversibly affixed to the main display 210. The fastener 300 can extend over part of or across the entire area in which the two backplates 130, 230 overlap. For example, a glue can be applied across the entirety of the mutually contacting surfaces of the backplates 130, 230. In some embodiments, the glue only extends along the edge of a backplate. In other embodiments, the main display 210 can be attached to the sub-display 110 by an external structure which clamps down on or provides pressure to compress the main display 210 against the sub-display 110.

It will be appreciated that the overall thickness of the two-sided display 100 is governed by the thicknesses of various features, including: 1) the backplates 130, 230; and 2) the desiccant 170, 270. The thickness of one or both of the backplates 130, 230 and the desiccant 170, 270 can be reduced to decrease the thickness of the two-sided display 100.

The useful lifetime of the interferometric modulators 150, 250 can be extended by protecting those interferometric modulators from mechanical interference, excessive moisture, and other potentially damaging substances. In one embodiment, the backplates 130, 230 are used to provide this protection. Preferably, they are spaced a distance from the interferometric modulators 150, 250 to allow a margin for mechanical deformation of the backplates 130, 230 and/or the transparent substrates 120, 220, which deformation can otherwise cause the backplates 130, 230 to contact and damage the interferometric modulators 150, 250. In some embodiments, the backplates can be provided with large recess, into which the interferometric modulators can fit, while still being spaced from a back wall of the backplates.

The edge of a backplate 130, 230 can be attached with sealant 140, 240 near the edge of the transparent substrates 120, 220 to prevent mechanical interference from reaching and potentially damaging the interferometric modulators 150, 250 fabricated on the backside of the transparent substrates 120, 220. Together, the backplates 130, 230, the sealants 140, 240 and the transparent substrates 120, 220 seal the interferometric modulators 150, 250 from the ambient environment to prevent moisture and other potentially detrimental gases, liquids and solids from reaching those interferometric modulators 150, 250.

The backplates 130, 230 need not serve any role as active or functional components of a display. Thus, few requirements and specifications related to the functionality of the display 100 are placed on the backplates 130, 230. Rather, as noted above, the backplates 130, 230 are principally structural and sealing components. Accordingly, the backplates 130, 230 can be transparent or opaque, conductive or insulating, essentially two-dimensional or projecting appreciably into a third dimension. In one embodiment, the backplates 130, 230 can be made of material completely unsuitable for use as a transparent display substrate, such as an opaque metal. In one embodiment, the backplates 130, 230, like the transparent substrates 120, 220, are formed of glass, which has advantages for use in production, including ease of scoring and subdividing sheets of the material.

In some arrangements, the backplates 130, 230 can be employed to hold electronics, and the footprint of one or both of the backplates 130, 230 can be expanded well beyond the active display area formed by the interferometric modulators 150, 250 so that the backplates 130, 230 essentially become a “backbone” for and the principal structural element of a device which contains the interferometric modulators 150, 250. The backplates 130, 230 preferably have sufficient stiffness to provide much of the mechanical support and to maintain the structural integrity of the display 100. In some embodiments, if much of the supporting function is provided by the backplates 130, 230, then the transparent substrates 120, 220 can be made extremely thin. In addition, in some embodiments, part of the transparent substrates 121, 220 can extend beyond the backplates 131, 231, respectively to accommodate driver circuits 180a, 180b (FIG. 9).

In general, reductions in the thicknesses of backplates have been thought to be limited by the fact that the stiffness of many backplate materials is proportional to the cube of the thickness of the material. Consequently, the ability to use thin backplate layers has been considered limited due to requirements for stiffness and the strong effect of thickness reduction on stiffness. As a result, approaches which remove one or more of the backplates 130, 230 have been favored for reducing the overall thickness of the two-sided display 100.

However, the thickness required for the backplates of a two-sided display can be less than that expected for an otherwise similar standalone one-sided display. For example, one or both of the backplates 130, 230 can be made thinner than would be suitable for a standalone one-sided display having similar screen dimensions; that is, one or both of the backplates 130, 230 can be made having a thickness or stiffness that does not satisfy the requirements for a similar standalone one-sided display comprising the backplate 130 or 230 and the transparent substrate 150 or 250, respectively. Advantageously, their suitability for use in one-sided displays is of minimal importance, since these thin backplates 130, 230 can reinforce and stiffen each other when attached together to form the two-sided display 100. Thus, in some embodiments, one or both of the backplates 130, 230 of the two-sided display 100 do not meet the requirements for a one-sided display, although they meet or exceed the stiffness requirements for a two-sided display. Preferably, the aggregate thickness of the backplates 130, 230, including any space between the backplates 130, 230 (such as resulting from fasteners 300) is 1.4 mm or less, more preferably, about 1.2 mm or less and, even more preferably, about 1.0 mm or less. Each backplate 130, 230 can have the same or different thicknesses. The thickness of at least one of the backplates 130, 230 is preferably about 0.35 mm or less, more preferably, about 0.2 mm or less. It will be appreciated that the fastener 300, e.g., an adhesive, disposed between the backplates 130, 230 can also add to the total thickness of the two-sided display. In some embodiments, the fastener 300 is as thin as possible. In other embodiments, the fastener 300 can be provided with reinforcing elements (e.g., embedded metal ribs) which can reinforce the backplates 130, 230. The thickness of the fastener 300 can be about 0.02 mm to about 0.1 mm in some embodiments, such that the aggregate thickness of the backplates 130, 230 and the fastener 300 is about 0.8 mm or less and, more preferably, about 0.5 mm or less.

With reference to FIGS. 9-13 and 15, one of the sub and main displays 110, 210 can be smaller than the other. For example, the sub-display 111-115, 310 (FIGS. 9-13 and 15) can be smaller than the main display 210 in some embodiments. While fasteners attaching together the backplates 130, 230 are not illustrated in the remaining figures for ease of illustration, it will be appreciated that any of the fastening methods discussed above with reference to FIG. 8 can be applied to attaching together the displays of FIGS. 9-15.

With reference to FIG. 9, because thickness reduction in backplates 131, 231 of sub and main displays 111, 211, respectively, is preferably achieved where both backplates overlap, the larger backplate 231 is provided with a cavity or indentation 280 into which the backplate 131 can be accommodated. Over the area of the cavity 280, the backplates 131, 231 reinforce one another and one or both backplates 131, 231 in this area can be made thinner than would be required for the backplate of a standalone one-sided display. Outside the cavity 280, the backplate 231 is not reinforced by the backplate 131 and preferably has sufficient thickness to provide the desired stiffness for the display 211 and the two-sided display 101. The backplate 131 can be sealed to a transparent substrate 121 by sealant 141 to form a cavity 161 in the sub-display 111. Pixel elements 151 and desiccant 171 can be provided in the cavity 161. The driver circuits 180a, 180b can be provided on the transparent substrates 121, 220, respectively, to control the sub and main displays 111, 211, respectively. In other embodiments, only one of the driver circuits 180a, 180b is provided and the single driver circuit is used to control both displays 111 and 121, e.g., by connecting to one or both of the displays 111, 121 using a flex cable.

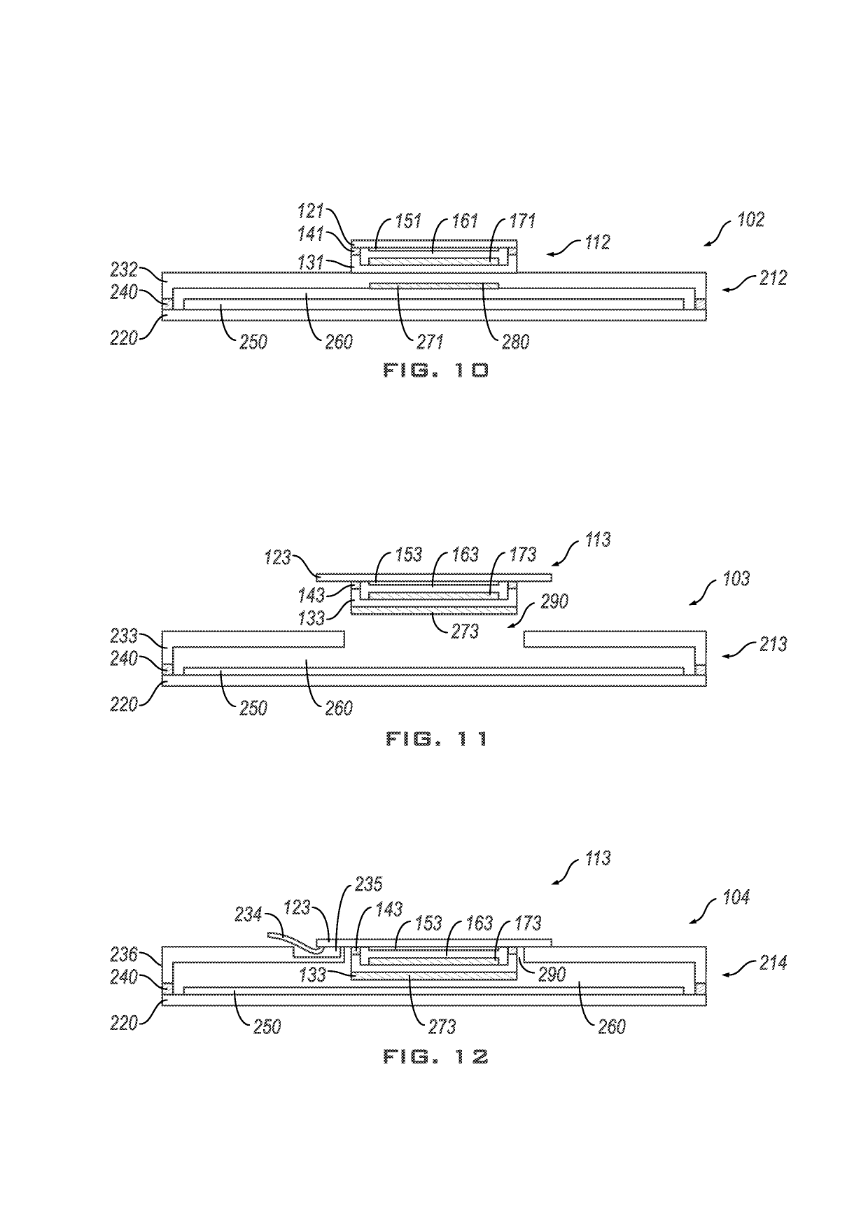

With reference to FIG. 10, a two-sided display 102 can have the cavity 280 formed on a side of a backplate 232 opposite that shown in FIG. 9. In this arrangement, the cavity 280 can at least partially accommodate desiccant 271 in main display 212. The sub-display 111 is mounted on the backplate 232, opposite the cavity 280. In other respects, the two-sided display 102 can be similar to the two-sided display 101 of FIG. 9.

Advantageously, the arrangements of FIGS. 9 and 10 reduce the thickness of the display 100 occupied by the combination of the desiccant 270, 271, the backplate 231, 232 and the backplates 131, 132. It will be appreciated that, in FIG. 10, the desiccant 271 is accommodated in the indentation 280, thereby allowing the thickness of the cavity 260 to be reduced, relative to FIG. 9, by the thickness of the desiccant 270.

With reference to FIGS. 11 and 12, backplate 233 of main display 213 can be provided with a hole 290. The hole 290 is sized and shaped to accommodate the backplate 133 of sub-display 113. The backplate 133 is also provided with desiccant 273. Another part of the sub-display 113, such as transparent substrate 123, extends beyond the hole and seals against the backplate 233 to protect pixel elements 250, e.g., interferometric modulators, from, e.g., outside moisture. The sub-display 113 comprises pixel elements 153 and desiccant 173 inside a cavity 163 formed by transparent substrate 123 and the backplate 133. The transparent substrate 123 and the backplate 133 are joined together by the sealant 143 to form two-sided displays 103 and 104. In some embodiments, the sub-display 113 can be electronically connected to driver circuits or other electronics by a flex cable 234, which can be attached to the sub-display 113 before affixing the sub-display 113 to a backplate 236 of a main display 214 to form the two-sided display 104 (FIG. 12). After the sub-display 113 and the backplate 236 are joined together, the flex cable 234 can be accommodated in a recess 235 provided in the backplate 236.

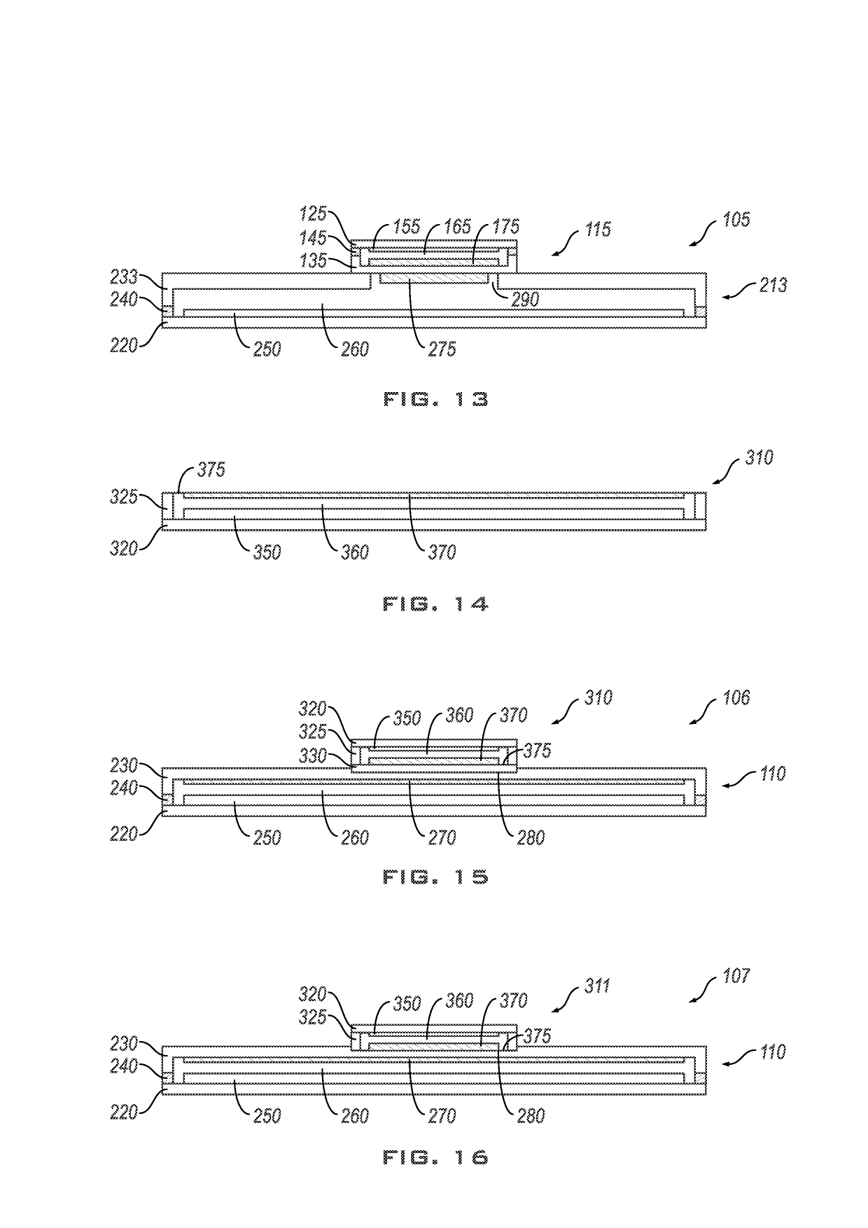

With reference to FIG. 13, the relative sizes and shapes of the hole 290 and backplate 135 can be chosen so that the backplate 135 extends beyond the hole 290, rather than into it, in a two-sided display 105. In this arrangement, the backplate 135 seals against the backplate 233. Desiccant 275 for the cavity 260 of the main display 213 is provided on the backplate 135 and is accommodated in the hole 290. The sub-display 115 also has desiccant 175 provided in a cavity 165 containing pixel elements 155. The backplate 135 and transparent substrate 125 are joined together by the sealant 145 to form the cavity 165.

Relative to an arrangement without a hole, e.g., as illustrated in FIG. 8, the arrangements of FIGS. 11-12 can reduce the thickness of the display 100 by the thickness of the backplate 130 or more, depending on how deeply the sub-display 113 extends into the main display 213.

It will be appreciated that the embodiments illustrated in FIGS. 9 and 10 advantageously allow the main and sub-displays 111 and 211, and 112 and 212, respectively, to be tested independently of each other. The embodiments of FIGS. 11-12 advantageously allow the sub-displays 113 to be tested independently of the main displays 213, 214. In each case, production yields can be increased since the one or both of the main and sub-displays can be tested independently, thereby reducing the possibility that both displays will need to be thrown away if they are permanently attached to each other and one display is later found to be defective.

In some arrangements, the displays can be tested before a backplate is attached. For example, with reference to FIG. 14, the display 310 can be provided with a film 375 which has sufficient mechanical integrity and forms a sufficiently airtight seal for the function of the display 310, including the interferometric modulators 350, to be tested. The film 375 is attached to and spaced from a transparent substrate 320 via supports 325. The film 375 is preferably provided with desiccant 370. The film 375 can comprise various materials that can form a thin sheet, including, e.g., various polymers, glass, ceramic and foil, especially metal foil.

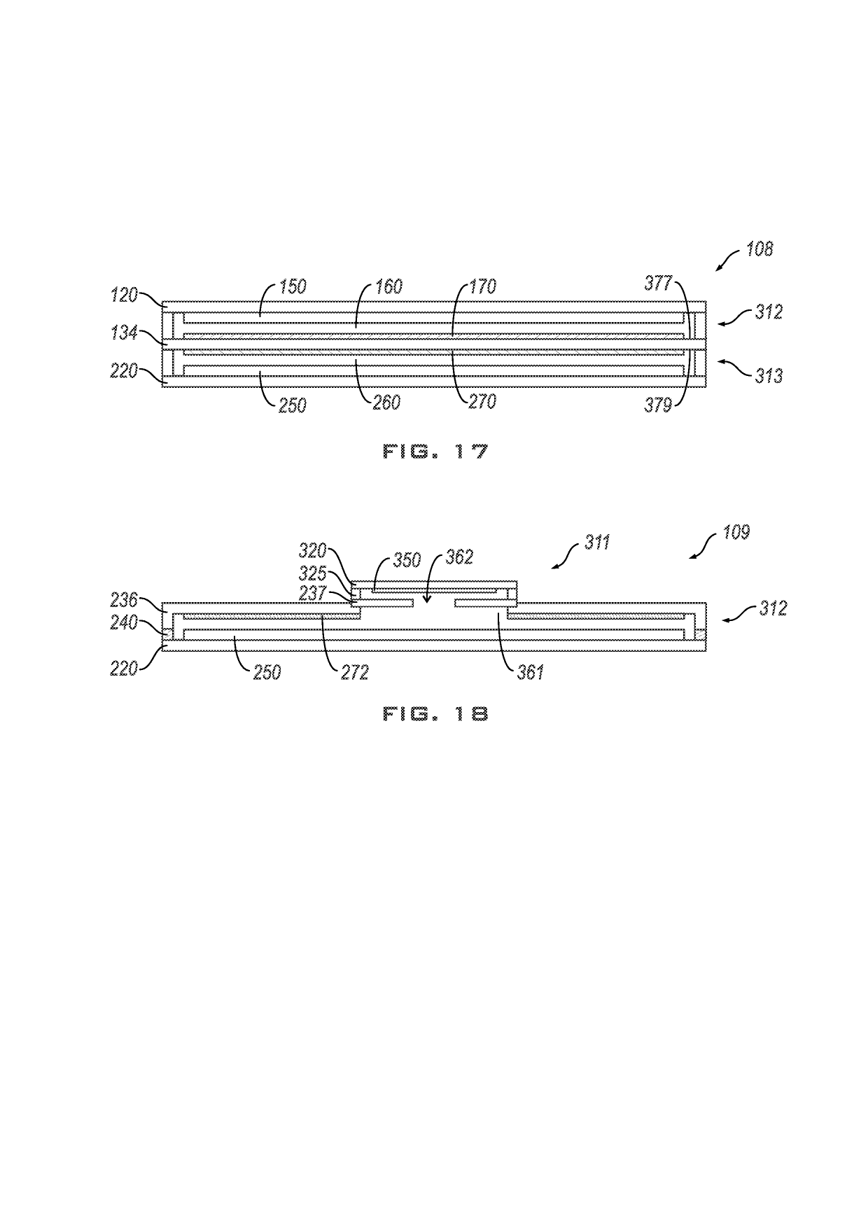

After the display 310 is tested, a backplate can optionally be attached. Depending on the size of the display 310 and the configuration of the backplate, the display 310 can then act as any of the sub or main displays discussed herein. An example is shown in FIG. 15, in which the display 310 is used as a sub-display after being attached to a backplate 330 to form a two-sided display 106. The backplate 330 fits into the recess 280 of the backplate 230 of the main display 110. In other arrangements, an example of which is shown in FIG. 16, because individual testing of the displays has already been accomplished, a backplate is not attached to display 311 and the main and sub-displays 110, 311 can share a single backplate 230 in a two-sided display 107. The thin film 375 of the display 311 can be joined directly with the backplate 230. Note that FIG. 16 shows the backplate 230 provided with a recess 280, which is optional and can be omitted in other embodiments. In addition, in some arrangements, both the main and sub-displays can be sealed with a thin film, which allows for individual testing of each display before the displays are attached to a common backplate. For example, with reference to FIG. 17, a two-sided display 108 can be formed with sub-display 312 and main display 313, which were sealed with thin films 377 and 379, respectively, before being attached to backplate 134. In other embodiments, the thin films 377, 379 can be removed before attachment of the sub-display 312 and main display 313 to the backplate 134, to which desiccant 170 can be attached.

In some embodiments, the thin film can be removed after testing. For example, after removal, the sub-display can be affixed to another display to form a two-sided display. It will be appreciated that removing the thin film may leave the sub-display without desiccant. In such cases, with reference to FIG. 18, a sub-display 311 is preferably sealed to a backplate 236 of another display, e.g., main display 312, provided with desiccant 272 on its backplate 236, thereby forming a two-sided display 109. The subdisplay 311 can be provided with a backplate 237, attached before sealing the sub-display 311 to the backplate 236 and after removing the thin film. The backplate 237 is provided with a hole 362 to allow the display 311 to form a continuous open volume 361 with the interior of the other display 312, thereby allowing both displays 311, 312 to share the desiccant 272.

It will be appreciated that the various single-sided displays, e.g., sub and main displays, discussed herein can be formed by various methods known in the art. Depending on whether the backplates of the displays completely seal the display, the displays can then be individually tested. Two of these displays, at least one of which is independently testable, can be attached back-to-back, to form a two-sided display. This back-to-back attachment preferably entails rigidly fixing the backplates of the two back-to-back displays to one another. As discussed above, the displays can be attached to one another using various methods, including glue, adhesive tape and mechanical fasteners.

In other cases, a thin sealing film is used to seal a partially fabricated display before a backplate is attached. The display is then tested. After testing, a backplate is attached. The display can then be attached to another display, which may or may not have been formed with a thin sealing film.

It will be appreciated by those skilled in the art that various other omissions, additions and modifications may be made to the methods and structures described above without departing from the scope of the invention. All such modifications and changes are intended to fall within the scope of the invention, as defined by the appended claims.

We claim:

1. A two-sided display apparatus, the apparatus comprising:
a first display device having a first viewing surface, a first backplate, and a first cavity formed between the first viewing surface and the first backplate; and
a second display device having a second viewing surface, a second backplate, and a second cavity formed between the second viewing surface and the second backplate,
wherein the second backplate is coupled to the first backplate such that the first viewing surface faces away from the second viewing surface, and
wherein the first and second backplates each have an opening formed therethrough to form a continuous open volume encompassing the first cavity and the second cavity.

2. The display apparatus of claim 1, wherein the first display device includes one of a reflective display device and a non-reflective display device, and wherein the second display device includes the other of the reflective display device and the non-reflective display device.

3. The display apparatus of claim 2, wherein the non-reflective display device includes one of a plasma display, an electroluminescent (EL) display, and a liquid crystal display (LCD).

4. The display apparatus of claim 2, wherein the non-reflective display device includes an organic light-emitting diode (OLED) display.

5. The display apparatus of claim 2, wherein the reflective display device includes a microelectromechanical systems (MEMS) display.

6. The display apparatus of claim 5, wherein the reflective display device includes an array of interferometric modulators.

7. The display apparatus of claim 1, wherein the first viewing surface has a larger viewing area than the second viewing surface.

8. The display apparatus of claim 1, further comprising a desiccant disposed in the continuous open volume.

9. The display apparatus of claim 8, wherein the desiccant is disposed in the first cavity.

10. The display apparatus of claim 1, further comprising a fastener that affixes the first backplate to the second backplate and that forms a substantially air-tight seal between the first and second backplates.

11. The display apparatus of claim 1, further comprising a first transparent substrate that includes the first viewing surface and a second transparent substrate that includes the second viewing surface.

12. The display apparatus of claim 11, further comprising a first array of pixel elements disposed between the first transparent substrate and the first backplate, and a second array of pixel elements disposed in the second cavity between the second transparent substrate and the second backplate.

13. The display apparatus of claim 12, wherein at least one of the first array and the second array of pixel elements is disposed directly on the first transparent substrate or on the second transparent substrate, respectively, such that there is a gap between the first array of pixel elements and the first backplate or between the second array of pixel elements and the second backplate, respectively, and wherein the gap extends across substantially the entire array.

14. The display apparatus of claim 1, wherein a combined thickness of the first and the second backplates is about 1.4 mm or less.

15. The display apparatus of claim 14, wherein the combined thickness is about 1.0 mm or less.

16. The display apparatus of claim 1, wherein the first backplate comprises a recess sized and shaped to accommodate the second backplate, and wherein the second backplate is disposed within the recess of the first backplate.

17. A method of manufacturing a two-sided display device, the method comprising:
providing a first display device having a first viewing surface, a first backplate, and a first cavity formed between the first viewing surface and the first backplate, the first backplate having a first opening formed therethrough;
providing a second display device having a second viewing surface, a second backplate, and a second cavity formed between the second viewing surface and the second backplate, the second backplate having a second opening formed therethrough; and
coupling the second backplate to the first backplate such that the first viewing surface faces away from the second viewing surface to form a continuous open volume encompassing the first cavity and the second cavity.

18. The method of claim 17, further comprising:
disposing a first array of pixel elements between the first transparent substrate and the first backplate; and
disposing a second array of pixel elements in the second cavity between the second transparent substrate and the second backplate.

19. The method of claim 18, wherein the first display device includes one of a reflective display device and a non-reflective display device, and wherein the second display device comprises the other of the reflective display device and the non-reflective display device.

20. The method of claim 18, wherein disposing the first array of pixel elements includes performing deposition and etching processes to fabricate the first set of pixel elements, and wherein disposing the second array of pixel elements includes performing deposition and etching processes to fabricate the second set of pixel elements.

21. The method of claim 19, wherein the non-reflective display device includes an organic light-emitting diode (OLED) display.
